(19) United States
(12) Patent Application Publication
(10) Pub. No.: US 2024/0105759 A1
(43) Pub. Date: Mar. 28, 2024

(54) APPARATUS AND METHOD FOR FABRICATING DISPLAY PANEL

(71) Applicant: Samsung Display Co., LTD., Yongin-si (KR)

(72) Inventor: Jeong Won HAN, Yongin-si (KR)

(73) Assignee: Samsung Display Co., LTD., Yongin-si (KR)

(21) Appl. No.: 18/342,876

(22) Filed: Jun. 28, 2023

(30) Foreign Application Priority Data
Sep. 27, 2022 (KR) 10-2022-0122053

(51) Int. Cl. H01L 27/15; H01L 33/00; H01L 33/44

(52) U.S. Cl. CPC H01L 27/156; H01L 33/0016; H01L 33/005; H01L 33/44

(57) ABSTRACT

The disclosure provides an apparatus for fabricating a display panel. The display device includes a transfer member having adhesiveness or stickiness and thereby capable of being bonded to light-emitting elements and a transport member transferring and bonding the light-emitting elements which are aligned on a donor substrate onto a circuit substrate by the transfer member, the transport member includes a laser transmitter formed of a material capable of transmitting laser light, a transport head capable of moving vertically and horizontally and surrounding side surfaces of the laser transmitter, and a head chuck disposed on a surface of the transport head to surround the side surfaces of the laser transmitter, having an adsorption function, and capable of being attached to, or detached from, the transfer member.

### CROSS-REFERENCE TO RELATED APPLICATION(S)

application claims priority to and benefits of Korean Patent Application No. 10-2022-0122053 under 35 U.S.C. § 119 filed on Sep. 27, 2022 in the Korean Intellectual Property Office, the entire contents of which are incorporated herein by reference.

### BACKGROUND

### 1. Technical Field

The disclosure relates to an apparatus and method for fabricating a display panel.

### 2. Description of the Related Art

Display devices are becoming more important with developments in multimedia technology. Accordingly, various display devices such as an organic light-emitting diode (OLED) display device, a liquid crystal display (LCD) device, and the like have been used.

A display device may include a display panel such as a light-emitting display panel or an LCD panel. The light-emitting display panel may include light-emitting elements such as, for example, light-emitting diodes (LEDs). Examples of the LEDs include organic LEDs (OLEDs) using an organic material as a fluorescent material and inorganic LEDs using an inorganic material as a fluorescent material.

To fabricate a display panel using inorganic LEDs, manufacturing equipment for arranging microLEDs on the substrate of a display panel needs to be developed.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Aspects of the disclosure provide an apparatus and method for fabricating a display panel, which are capable of performing the transfer and the bonding of light-emitting elements at the same time with the use of transport members with laser transmitters.

Aspects of the disclosure also provide an apparatus and method for fabricating a display panel, which are capable of transferring light-emitting elements on a donor substrate onto a circuit substrate with the use of disposable transfer members and thereby addressing any transfer defects that may be caused by the contamination of the transfer members and a head chuck.

However, aspects of the disclosure are not restricted to those set forth herein. The above and other aspects of the disclosure will become more apparent to one of ordinary skill in the art to which the disclosure pertains by referencing the detailed description of the disclosure given below.

According to an aspect of the disclosure, an apparatus for fabricating a display panel may comprise a transfer member having adhesiveness or stickiness that bonds to light-emitting elements; and a transport member transferring and bonding light-emitting elements which are aligned on a donor substrate of the light-emitting elements onto a circuit substrate by the transfer member, wherein the transport member may include a laser transmitter formed of a material that transmits laser light; a transport head that moves vertically and horizontally and surrounds side surfaces of the laser transmitter; and a head chuck disposed on a surface of the transport head to surround the side surfaces of the laser transmitter, having an adsorption function, and attached to, or detached from, the transfer member.

The transfer member may include a stamp layer, that has adhesiveness or stickiness, and a base layer, that is disposed on a surface of the stamp layer, and is formed of a material that transmits laser light.

The head chuck may be attachable to, or detachable from the base layer.

The transfer member may include a transfer part that overlaps the laser transmitter in a plan view and an edge part that overlaps the head chuck in a plan view.

An edge part of the base layer may be thinner than a transfer part of the base layer.

The stamp layer may be formed only in the transfer part.

The head chuck may form a substantially acute angle with the transport head.

The edge part may be folded along slopes of the head chuck.

The light-emitting elements may include n-type semiconductors; active layers; p-type semiconductors; first contact electrodes and second contact electrodes; and may further include bonding members on surfaces of the first contact electrodes and surfaces of the second contact electrodes.

The apparatus for fabricating a display panel may further comprise a heating member applying laser light to the bonding members through the laser transmitter and the transfer member.

The circuit substrate may include a flux applied on a surface of the circuit substrate.

According to an embodiment, a method of fabricating a display panel may comprise adsorbing, by a transport member, a transfer member by a chuck; picking up, by the transport member, light-emitting elements from a donor substrate by the transfer member; bonding, by the transport member, the light-emitting elements onto a circuit substrate by the transfer member by placing the light-emitting elements on the circuit substrate and applying laser light; separating, by the transport member, the transfer member from the circuit substrate and detaching, by the transport member, the transfer member by releasing the chuck.

The method of fabricating a display panel may further comprise rinsing off a flux from the circuit substrate in case that the bonding of the light-emitting elements onto the circuit substrate is complete.

The transfer member may include a stamp layer that has adhesiveness or stickiness; and a base layer that is disposed on a surface of the stamp layer, and is formed of a material that transmits laser light.

The transport member may include a laser transmitter that transmits laser light; a transport head that moves vertically and horizontally and surrounds side surfaces of the laser transmitter; and a head chuck disposed on a surface of the transport head to surround the side surfaces of the laser transmitter, having an adsorption function, and attached to, or detached from, the transfer member.

The light-emitting elements may include n-type semiconductors; active layers; p-type semiconductors; first contact electrodes and second contact electrodes; and bonding members on surfaces of the first contact electrodes and surfaces of the second contact electrodes.

The bonding of the light-emitting elements onto the circuit substrate, may comprise placing, by the transport member, the light-emitting elements such that the laser transmitter, the transfer member, the light-emitting elements, the bonding members, and the circuit substrate overlap in a plan view.

A heating member may apply laser light to the bonding members through the laser transmitter and the transfer member.

The transfer member may include a transfer part that overlaps the laser transmitter in a plan view and an edge part that overlaps the head chuck in a plan view, and the stamp layer is formed only in the transfer part.

The head chuck may form a substantially acute angle with the transport head.

The transfer member may include a transfer part that overlaps the laser transmitter in a plan view and an edge part that overlaps the head chuck in a plan view, and the adsorbing of the transfer member by the chuck, comprises folding the edge part along slopes of the head chuck.

According to the aforementioned and other embodiments, the transfer and bonding of light-emitting elements can both be performed at the same time by a transport member with a laser transmitter.

Also, any transfer defects that may be caused by contaminated transfer members can be addressed by transferring light-emitting elements from a donor substrate onto a circuit substrate with the use of disposable transfer members.

Also, as the transfer members are removed after the bonding of light-emitting elements onto a circuit substrate, a flux can be prevented from being in direct contact with the laser transmitter, and as a result, the contamination of the laser transmitter can be prevented.

It should be noted that the effects of the disclosure are not limited to those described above, and other effects of the disclosure will be apparent from the following description.

### BRIEF DESCRIPTION OF THE DRAWINGS

The above and other aspects and features of the disclosure will become more apparent by describing in detail embodiments thereof with reference to the attached drawings, in which:

FIG. 1 is a schematic plan view of a display device according to an embodiment;

FIG. 2 is a schematic plan view of a pixel of FIG. 1;

FIG. 3 is a schematic plan view of a pixel of FIG. 1;

FIG. 4 is a schematic cross-sectional view taken along line A-A′ of FIG. 2;

FIG. 5 is a block diagram of an apparatus for fabricating a display panel according to an embodiment;

FIG. 6 is a schematic perspective view of a transfer member and a transport member according to an embodiment;

FIG. 7 is a schematic cross-sectional view taken along line A-A′ of FIG. 6;

FIG. 8 is a flowchart illustrating a method of fabricating a display panel according to an embodiment;

FIGS. 9 through 18 are schematic cross-sectional views illustrating the method of FIG. 8;

FIG. 19 is a schematic perspective view of a transfer member and a transport member according to an embodiment;

FIG. 20 is a schematic cross-sectional view taken along line B-B′ of FIG. 19;

FIGS. 21 through 26 are schematic cross-sectional views illustrating a method of fabricating a display panel using the transfer member and the transport member of FIGS. 19 and 20;

FIG. 27 is a schematic perspective view of a transfer member and a transport member according to an embodiment;

FIG. 28 is a schematic cross-sectional view taken along line C-C′ of FIG. 27; and

FIGS. 29 through 34 are schematic cross-sectional views illustrating a method of fabricating a display panel using the transfer member and the transport member of FIGS. 27 and 28.

### DETAILED DESCRIPTION OF THE EMBODIMENTS

Embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity. For example, in the drawings, sizes, thicknesses, ratios, and dimensions of the elements may be exaggerated for ease of description and for clarity. Like numbers refer to like elements throughout.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side.

The terms “overlap” or “overlapped” mean that a first object may be above or below or to a side of a second object, and vice versa. The term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object or other object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that “connected” or “coupled” may also include a physical connection or coupling.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

As used herein, the singular forms, “a,” “an,” and “the” are intended to include the plural forms as well, unless the context clearly indicates otherwise.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described in detail with reference to the accompanying drawings.

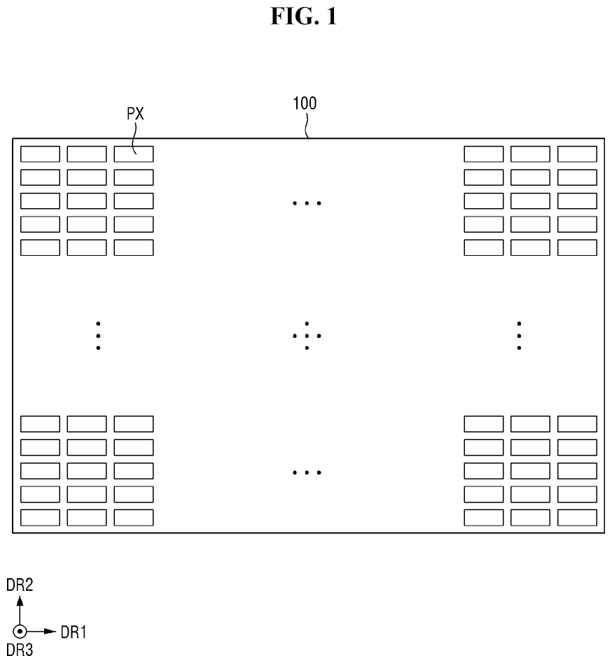

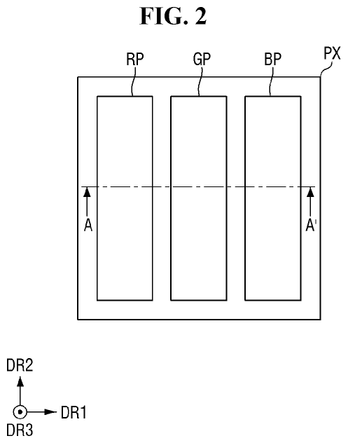

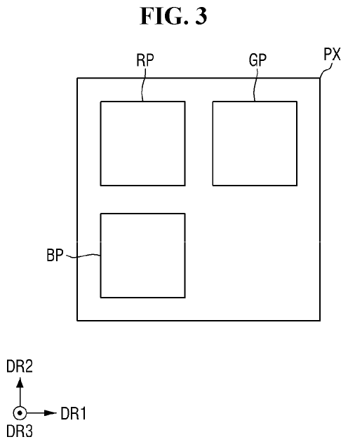

FIG. 1 is a schematic plan view of a display device according to an embodiment. FIG. 2 is a schematic plan view of a pixel of FIG. 1. FIG. 3 is a schematic plan view of a pixel of FIG. 1.

Referring to FIGS. 1 through 3, a display device 100, which is a device for displaying a moving or still image, may be used not only as the display screen of a portable electronic device such as a mobile phone, a smartphone, a tablet personal computer (PC), a smartwatch, a watchphone, a mobile communication terminal, an electronic notepad, an electronic book (e-book), a portable multimedia player (PMP), a navigation device, or a ultra-mobile PC (UMPC), but also as the display screen of various other products such as a television (TV), a laptop computer, a monitor, a billboard, or an Internet-of-Things (IoT) device.

A display panel 100 may be formed into a rectangular shape having long sides in a first direction DR1 and short sides in a second direction DR2, which intersects the first direction DR1. The corners where the long sides and the short sides of the display panel 100 meet may be right-angled or may be rounded to have a selectable curvature. The planar shape of the display panel 100 is not particularly limited, and the display panel 100 may have various other shapes such as a non-tetragonal polygonal shape, a circular shape, or an elliptical shape. For example, the display panel 100 may be formed to be flat, but the disclosure is not limited thereto. In another example, the display panel 100 may include curved parts, which are formed at both ends of the display panel 100 and have a uniform or varying curvature. The display panel 100 may be formed to be flexible such as bendable, foldable, or rollable.

The display panel 100 may include pixels PX, which are for displaying an image, scan lines, which extend in the first direction DR1, and data lines, which extend in the second direction DR2. The pixels PX may be arranged or disposed in a matrix along the first and second directions DR1 and DR2.

Referring to FIGS. 2 and 3, a pixel PX may include subpixels (RP, GP, and BP. FIGS. 2 and 3 illustrate that a pixel PX may include three subpixels, for example, first, second, and third subpixels RP, GP, and BP, but the disclosure is not limited thereto.

The first, second, and third subpixels RP, GP, and BP may be connected to one of the data lines and at least one of the scan lines.

The first, second, and third subpixels RP, GP, and BP may have a rectangular, square, or rhombus shape in a plan view. For example, referring to FIG. 2, the first, second, and third subpixels RP, GP, and BP may have a rectangular shape having short sides in the first direction DR1 and long sides in the second direction DR2. In another example, referring to FIG. 3, the first, second, and third subpixels RP, GP, and BP may have a square or rhombus shape having four equal sides in the first and second directions DR1 and DR2. It is to be understood that the shapes disclosed herein may also include shapes substantial to the shapes disclosed herein.

Referring to FIG. 2, the first, second, and third subpixels RP, GP, and BP may be arranged or disposed side-by-side in the first direction DR1. By way of example, the first subpixel RP and one of the second and third subpixels GP and BP may be arranged or disposed side-by-side in the first direction DR1, and the first subpixel RP and the other one of the second and third subpixels GP and BP may be arranged or disposed side-by-side in the second direction DR2. For example, referring to FIG. 3, the first and second subpixels RP and GP may be arranged or disposed side-by-side in the first direction DR1, and the first and third subpixels RP and BP may be arranged or disposed side-by-side in the second direction DR2.

By way of example, the second subpixel GP and one of the first and third subpixels RP and BP may be arranged or disposed side-by-side in the first direction DR1, and the second subpixel GP and the other one of the first and third subpixels RP and BP may be arranged or disposed side-by-side in the second direction DR2. By way of example, the third subpixel BP and one of the first and second subpixels RP and GP may be arranged or disposed side-by-side in the first direction DR1, and the third subpixel BP and the other one of the first and second subpixels RP and GP may be arranged or disposed side-by-side in the second direction DR2

The first subpixel RP may include a first light-emitting element, which emits first light, the second subpixel GP may include a second light-emitting element, which emits second light, and the third subpixel BP may include a third light-emitting element, which emits third light. Here, the first light may be red-wavelength light, the second light may be green-wavelength light, and the third light may be blue-wavelength light. The red-wavelength light may be in the range of wavelengths in a range of about 600 nm to about 750 nm, the green-wavelength light may be in the range of wavelengths in a range of about 480 nm to about 560 nm, and the blue-wavelength light may be in the range of wavelengths in a range of about 370 nm to about 460 nm. However, the disclosure is not limited to this.

Each of the first, second, and third subpixels RP, GP and BP may include an inorganic light-emitting element having an inorganic semiconductor as a light-emitting element capable of emitting light. For example, the inorganic light-emitting element may be a flip chip-type micro-light-emitting diode (micro LED), but the disclosure is not limited thereto.

Referring to FIGS. 2 and 3, the first, second, and third subpixels RP, GP, and BP may have substantially a same area, but the disclosure is not limited thereto. At least one of the first, second, and third subpixels RP, GP, and BP may differ from the other subpixels. By way of example, only one of the first, second, and third subpixels RP, GP, and BP may have a different area from the other subpixels. By way of example, the first, second, and third subpixels RP, GP, and BP may all have different areas.

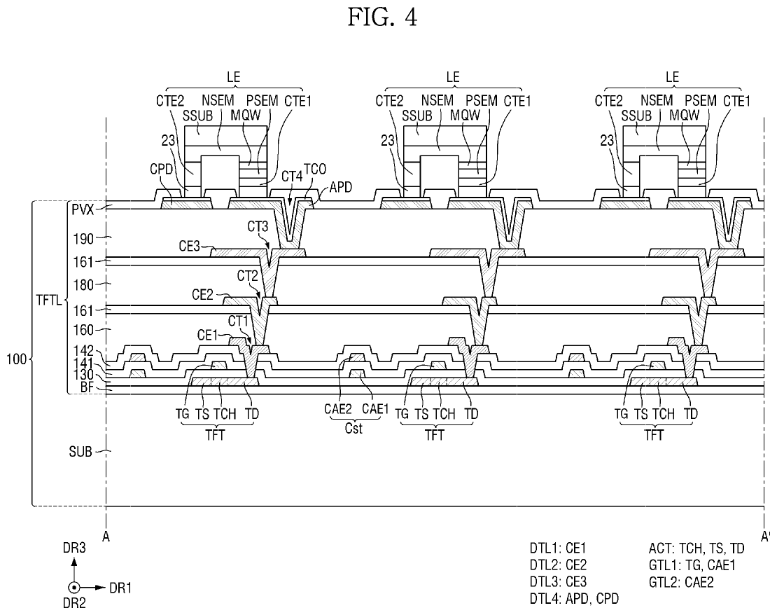

FIG. 4 is a schematic cross-sectional view taken along line A-A′ of FIG. 2.

Referring to FIG. 4, the display panel 100 may include a thin-film transistor (TFT) layer TFTL and light-emitting elements LE, which are disposed on a substrate SUB. The TFT layer TFTL may be a layer in which TFTs “TFT” are formed.

The TFT layer TFTL may include an active layer ACT, a first gate layer GTL1, a second gate layer GTL2, a first data metal layer DTL1, a second data metal layer DTL2, a third data metal layer DTL3, and a fourth data metal layer DTL4. The TFT layer TFTL may also include a buffer layer BF, a gate insulating layer 130, a first interlayer insulating layer 141, a second interlayer insulating layer 142, a first planarization layer 160, a first insulating layer 161, a second planarization layer 180.

The substrate SUB may be a base substrate or member for supporting the display device 100. The substrate SUB may be a glass-based rigid substrate, but the disclosure is not limited thereto. The substrate SUB may be a flexible substrate that is bendable, foldable, or rollable, in which case, the substrate SUB may include an insulating material such as a polymer resin (for example, polyimide (PI)).

The buffer layer BF may be disposed on one surface or a surface of the substrate SUB. The buffer layer BF may be a film for preventing the permeation of the air or moisture. The buffer layer BF may include inorganic films that may be alternately stacked each other. For example, the buffer layer BF may be formed as a multilayer layer in which at least one inorganic layer selected from among a silicon nitride layer, a silicon oxynitride layer, a silicon oxide layer, a titanium oxide layer, and an aluminum oxide layer may be alternately stacked each other. The buffer layer BF may be optional.

The active layer ACT may be disposed on the buffer layer BF. The active layer ACT may include an oxide semiconductor or a silicon semiconductor such as polycrystalline silicon, monocrystalline silicon, low-temperature polycrystalline silicon, or amorphous silicon.

The active layer ACT may include channels TCH, first electrodes TS, and second electrodes TD of the TFTs “TFT.” The channels TCH may be parts of the TFTs “TFT” that overlap h gate electrodes TG of the TFTs “TFT.” The first electrodes TS may be disposed on first sides of the channels TCH, and the second electrodes TD may be disposed on second sides of the channels TCH. The first electrodes TS and the second electrodes TD may be parts of the TFTs “TFT” that do not overlap the gate electrodes TD in a third direction DR3. The first electrodes TS and the second electrodes TD may be conductive regions obtained by doping a silicon semiconductor or an oxide semiconductor with ions.

The gate insulating layer 130 may be disposed on the active layer ACT. The gate insulating layer 130 may be formed as an inorganic layer such as, for example, a silicon nitride layer, a silicon oxynitride layer, a silicon oxide layer, a titanium oxide layer, or an aluminum oxide layer.

The first gate layer GTL1 may be disposed on the gate insulating layer 130. The first gate layer GTL1 may include the gate electrodes TG of the TFTs “TFT” and first capacitor electrodes CAE1. The first gate layer GTL1 may be formed as a single- or multilayer layer including at least one of molybdenum (Mo), aluminum (Al), chromium (Cr), gold (Au), titanium (Ti), nickel (Ni), neodymium (Nd), copper (Cu), and an alloy thereof.

The first interlayer insulating layer 141 may be disposed on the first gate layer GTL1. The first interlayer insulating layer 141 may be formed as an inorganic layer such as, for example, a silicon nitride layer, a silicon oxynitride layer, a silicon oxide layer, a titanium oxide layer, or an aluminum oxide layer.

The second gate layer GTL2 may be disposed on the first interlayer insulating layer 141. The second gate layer GTL2 may include second capacitor electrodes CAE2. The second gate layer GTL2 may be formed as a single- or multilayer layer including at least one of Mo, Al, Cr, Au, Ti, Ni, Nd, Cu, and an alloy thereof.

The second interlayer insulating layer 142 may be disposed on the second gate layer GTL2. The second interlayer insulating layer 142 may be formed as an inorganic layer such as, for example, a silicon nitride layer, a silicon oxynitride layer, a silicon oxide layer, a titanium oxide layer, or an aluminum oxide layer.

The first data metal layer DTL1, which may include first connecting electrodes CE1, first sub-pad, and data lines, may be disposed on the second interlayer insulating layer 142. The data lines may be integral with the first sub-pads, but the disclosure is not limited thereto. The first data metal layer DTL1 may be formed as a single- or multilayer layer including at least one of Mo, Al, Cr, Au, Ti, Ni, Nd, Cu, and an alloy thereof.

The first connecting electrodes CE1 may be connected to the first electrodes TS or the second electrodes TD of the TFTs “TFT” through first contact holes CT1, which penetrate the first and second interlayer insulating layers 141 and 142.

The first planarization layer 160, which is for planarizing step differences formed by the active layer ACT, the first gate layer GTL1, the second gate layer GTL2, and the first data metal layer DTL1, may be disposed on the first data metal layer DTL1. The first planarization layer 160 may be formed as an organic layer including an acrylic resin, an epoxy resin, a phenolic resin, a polyamide resin, or a polyimide resin.

The second data metal layer DTL2 may be disposed on the first planarization layer 160. The second data metal layer DTL2 may include the second connecting electrodes CE2 and second sub-pads PD2. The second connecting electrodes CE2 may be connected to the first connecting electrodes CE1 through second contact holes CT2, which penetrate the first insulating layer 161 and the first planarization layer 160. The second data metal layer DTL2 may be formed as a single- or multilayer layer including at least one of Mo, Al, Cr, Au, Ti, Ni, Nd, Cu, and an alloy thereof.

The second planarization layer 180 may be disposed on the second data metal layer DTL2. The second planarization layer 180 may be formed as an organic layer including an acrylic resin, an epoxy resin, a phenolic resin, a polyamide resin, or a polyimide resin.

The third data metal layer DTL3 may be disposed on the second planarization layer 180. The third data metal layer DTL3 may include third connecting electrodes CE3. The third connecting electrodes CE3 may be connected to the second connecting electrodes CE2 through third contact holes CT3, which penetrate and the second planarization layer 180. The third data metal layer DTL3 may be formed as a single- or multilayer layer including at least one of Mo, Al, Cr, Au, Ti, Ni, Nd, Cu, and an alloy thereof.

The third planarization layer 190 may be disposed on the third data metal layer DTL3. The third planarization layer 190 may be formed as an organic layer including an acrylic resin, an epoxy resin, a phenolic resin, a polyamide resin, or a polyimide resin.

The fourth data metal layer DTL4 may be disposed on the third planarization layer 190. The fourth data metal layer DTL4 may include anode pad electrodes APD, cathode pad electrodes CPD, and fourth sub-pads. The anode pad electrodes APD may be connected to the third connecting electrodes CE3 through fourth contact holes CT4, which penetrate the third planarization layer 190. The cathode pad electrodes CPD may receive a first power supply voltage, which is a low-potential voltage. The fourth data metal layer DTL4 may be formed as a single- or multilayer layer including at least one of Mo, Al, Cr, Au, Ti, Ni, Nd, Cu, and an alloy thereof.

A transparent conductive layer TCO, which is for improving the adhesion to first contact electrodes CTE1 and second contact electrodes CTE2 of the light-emitting elements LE, may be formed on the anode pad electrodes APD and the cathode pad electrodes CPD. The transparent conductive layer TCO may be formed of a transparent conductive oxide such as indium tin oxide (ITO) or indium zinc oxide (IZO). The transparent conductive layer TCO may be optional.

A passivation layer PVX may be disposed on the anode pad electrodes APD, and the cathode pad electrodes CPD. The passivation layer PVX may be disposed to cover the edges of each of the anode pad electrodes APD, and the cathode pad electrodes CPD. The passivation layer PVX may be formed as an inorganic layer such as, for example, a silicon nitride layer, a silicon oxynitride layer, a silicon oxide layer, a titanium oxide layer, or an aluminum oxide layer. The passivation layer PVX may be optional.

The light-emitting elements LE are illustrated as being flip chip-type micro LEDs in which the first contact electrodes CTE1 and the second contact electrodes CTE2 face the anode pad electrodes APD and the cathode pad electrodes CPD, but the disclosure is not limited thereto. The light-emitting elements LE may be inorganic light-emitting elements formed of an inorganic material such as GaN. The light-emitting elements LE may have a length of several to hundreds of micrometers in the first, second, and third directions DR1, DR2, and DR3. For example, the light-emitting elements LE may have a length of 100 μm in the first, second, and third directions DR1, DR2, and DR3.

The light-emitting elements LE may be grown from a semiconductor substrate such as a silicon wafer. The light-emitting elements LE may be transferred from the silicon wafer onto the anode pad electrodes APD and the cathode pad electrodes CPD on the substrate SUB. The first contact electrodes CTE1 and the anode pad electrodes APD may be bonded together by a bonding process. The second contact electrodes CTE2 and the cathode pad electrodes CPD may also be bonded together by a bonding process. The first contact electrodes CTE1 and the anode pad electrodes APD may be electrically connected through bonding electrodes 23. The second contact electrodes CTE2 and the cathode pad electrodes CPD may be electrically connected through the bonding electrodes 23.

For example, the bonding electrodes 23 may be disposed on surfaces of the light-emitting elements LE. The bonding electrodes 23 may be the products of a pressure melting process using laser. Here, the pressure melting process is a process in which the bonding electrodes 23 are melted by heat so that the light-emitting elements LE, the anode pad electrodes APD, and the cathode pad electrodes CPD are melted and fused together, and cool and solidify in case that the supply of laser light is terminated. As the conductivity of the light-emitting elements LE, the anode pad electrodes APD, and the cathode pad electrodes CPD is maintained while the light-emitting elements LE, the anode pad electrodes APD, and the cathode pad electrodes CPD are cooling and solidifying from a molten state, the light-emitting elements LE, the anode pad electrodes APD, and the cathode pad electrodes CPD can be electrically and physically connected together. Accordingly, the bonding electrodes 23 may be disposed on the first contact electrodes CTE1 and the second contact electrodes CTE2 of the light-emitting elements LE.

The bonding electrodes 23 may include, for example, Au, AuSn, PdIn, InSn, NiSn, Au—Au, AgIn, AgSn, Al, Ag, or carbon nanotube (CNT), and these materials may be used alone or in combination of one another. The bonding electrodes 23 may be formed on pad electrodes by various methods such as a deposition process or a screen printing method, depending on the type of the bonding electrode 23.

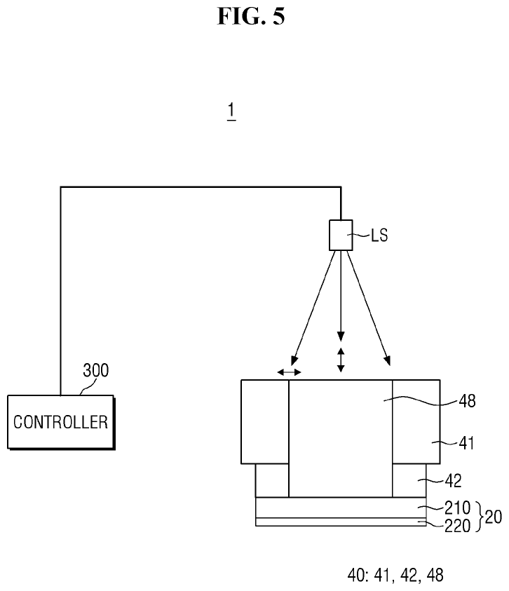

The light-emitting elements LE may be transferred onto the anode pad electrodes APD and the cathode pad electrodes CPD of the substrate SUB by a transfer member. This will be described later with reference to FIGS. 5 through 23.

The light-emitting elements LE may be light-emitting structures including base substrates SSUB, n-type semiconductors NSEM, active layers MQW, p-type semiconductors PSEM, the first contact electrodes CTE1, and the second contact electrodes CTE2.

The base substrate SSUB may be a sapphire substrate, but the disclosure is not limited thereto.

The n-type semiconductors NSEM may be disposed on the base substrates SSUB. For example, the n-type semiconductors NSEM may be disposed on the bottom surfaces of the base substrates SSUB. The n-type semiconductors NSEM may be formed of GaN doped with an n-type conductivity dopant such as Si, Ge, or Sn.

The active layers MQW may be disposed on parts of the n-type semiconductors NSEM. The active layers MQW may include a material with a single- or multi-quantum well structure. In a case where the active layers MQW include a material with a multi-quantum well structure, the active layers MQW may have a structure in which well layers and barrier layers may be alternately stacked each other. Here, the well layers may be formed of InGaN, and the barrier layers may be formed of GaN or AlGaN. However, the disclosure is not limited to this. By way of example, the active layers MQW may have a structure in which semiconductor materials with a large bandgap energy and semiconductor materials with a small bandgap energy may be alternately stacked each other or may include group-III to group-IV semiconductor materials depending on the range of wavelengths to be emitted.

FIG. 5 is a block diagram of an apparatus for fabricating a display panel according to an embodiment.

Referring to FIG. 5, an apparatus 1 for fabricating a display panel may include a transport member 40, a transfer member 20, and a controller 300. The apparatus 1 may further include a heating member LS.

The transfer member 20 may be formed of a material capable of transmitting laser light therethrough and may include a base layer 210 and a stamp layer 220, which is disposed on the base layer 210.

The base layer 210 may be formed of, for example, glass or plastic. The base layer 210 may include ultrathin glass. By way of example, the base layer 210 may be formed of polyethylene terephthalate (PET), polyurethane (PU), polyimide (PI), polycarbonate (PC), polyethylene (PE), polypropylene (PP), polysulfone (PSF), polymethyl methacrylate (PMMA), triacetyl cellulose (TAC), or cycloolefin polymer (COP).

The stamp layer 220 may be formed of an adhesive material or a sticky material. The adhesive material may be, for example, an optical clear adhesive (OCA) or a pressure sensitive adhesive (PSA), and the sticky material may be, for example, an acrylic material, a urethane-based material, or a silicone-based material. The stamp layer 220 may be formed to be thinner than the base layer 210.

The stamp layer 220 may be disposed on the base layer 210 to be adhered or bonded to the light-emitting elements LE.

The transport member 40 may include a transport head 41, a head chuck 42, and a laser transmitter 48.

The head chuck 42 may be attachable to, or detachable from, the transfer member 20.

The laser transmitter 48 may transmit laser light therethrough and may heat and press light-emitting elements LE during the bonding of the light-emitting elements LE.

The controller 300 may control the other elements of the apparatus 1. For example, the controller 300 may move the transport member 40 to any desired location along first, second, and third directions X, Y, and Z. For example, the controller 300 may control the attachment and detachment of the head chuck 42. For convenience, the transport member 40 may or will hereinafter be described as moving by itself, or the head chuck 42 may or will hereinafter be described as adsorbing the transfer member 20, without mentioning that the movement of the transport member 40 or the attachment or detachment of the head chuck 42 to or from the transfer member 20 is performed under the control of the controller 300.

The heating member LS may provide heat for bonding the light-emitting elements LE. For example, the heating member LS may provide laser light to the light-emitting elements LE through the laser transmitter 48 and the transfer member 20. As a result, the light-emitting elements LE may be pressure-melted and bonded.

The structure of the apparatus 1 will hereinafter be described.

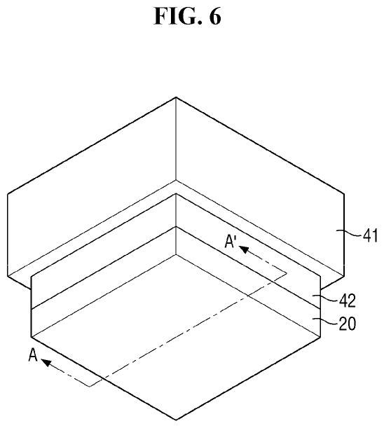

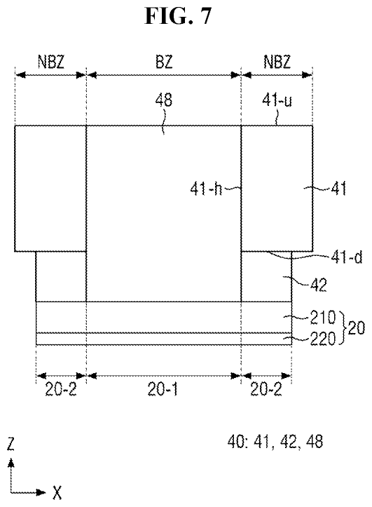

FIG. 6 is a schematic perspective view of a transfer member and a transport member according to an embodiment, and FIG. 7 is a schematic cross-sectional view taken along line A-A′ of FIG. 6.

Referring to FIGS. 6 and 7, a transport member 40 may include a transport head 41, a head chuck 42, and a laser transmitter 48.

The transport head 41, which is the body of the transport member 40, may include a central hole 41-h, which penetrates a top surface 41-u and a bottom surface 41-d of the transport head 41, in the middle.

The central hole 41-h may define a bonding area BZ that laser light transmits through and a non-bonding area NBZ that laser light does not transmit through. The bonding area BZ may be formed in the middle of the transport head 41, and the non-bonding area NBZ may be formed to surround the bonding area BZ.

The transport head 41 may apply pressure in one direction or in a direction during a bonding process. For example, the transport head 41 may apply pressure in a third direction Z. Accordingly, the laser transmitter 48, which is connected to the transport head 41, may apply pressure to light-emitting elements LE in the third direction Z.

The head chuck 42 is disposed in the non-bonding area NBZ and does not overlap the bonding area BZ. The head chuck 42 may be formed to surround the side surfaces of the laser transmitter 48.

The transport head 41, the head chuck 42, and an edge part 20-2 may be disposed to overlap the non-bonding area NBZ, and the laser transmitter 48 and a transfer part 20-2 may be disposed to overlap the bonding area BZ.

The head chuck 42 may be attachable to, or detachable from, the transfer member 20 via a chuck function. For example, the head chuck 42 may include any one of an electrostatic chuck, an adhesive chuck, a vacuum chuck, and a porous vacuum chuck. The head chuck 42 may adsorb the top surface of the transfer member 20.

The head chuck 42 may have a same size as, or a smaller size than, the top surface of the transfer member 20. As already mentioned above with reference to FIG. 5, the transfer member 20 may be formed of a material capable of transmitting laser light therethrough, and may include a base layer 210 and a stamp layer 220, which is disposed on the base layer 210. The head chuck 42 may adsorb one surface or a surface of the base layer 210 of the transfer member 20.

The transfer member 20 may include the transfer part 20-1, which overlaps the bonding area BZ, and the edge part 20-2, which overlaps the non-bonding area NBZ.

The transfer part 20-1 may overlap the bonding area BZ, but not with the non-bonding area NBZ. The edge part 20-2 may overlap the non-bonding area NBZ, but not with the bonding area BA.

The laser transmitter 48 may be disposed in the bonding area BZ. The laser transmitter 48 may be disposed in the central hole 41-h. The laser transmitter 48 may transmit laser light therethrough and may heat and press the light-emitting elements LE during the bonding of the light-emitting elements LE.

The laser transmitter 48 may be formed of one of, for example, quartz, sapphire, fused silica glass, or diamond. The physical properties of the laser transmitter 48 may differ depending on whether the laser transmitter 48 is formed of quartz or sapphire. For example, in case that irradiated with about 980 nm-laser light, a quartz-based laser transmitter 48 may have a transmittance in a range of about 85% to about 99%, and a sapphire-based laser transmitter 48 may have a transmittance in a range of about 80% to about 90%.

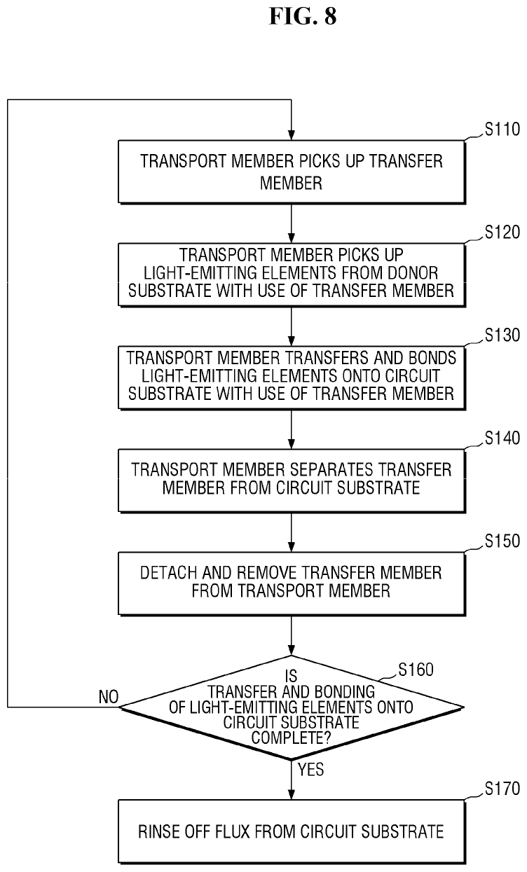

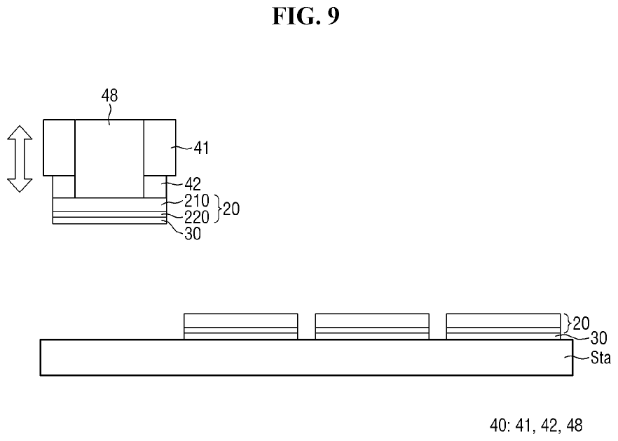

FIG. 8 is a flowchart illustrating a method of fabricating a display panel according to an embodiment. FIGS. 9 through 18 are schematic cross-sectional views illustrating the method of FIG. 8.

The fabrication of a display panel by the apparatus 1 through a laser bonding process will hereinafter be described with reference to FIGS. 8 through 18.

For example, light-emitting elements LE, which are targets to be transferred, may be transferred from a donor substrate DS onto a circuit substrate 10 by a transfer member 20.

Referring to FIGS. 8 and 9, the transport member 40 moves to pick up one of transfer members 20, which are placed on a support member Sta (S110).

Here, the support member Sta may support the transfer members 20. The transfer members 20 may be aligned and disposed on the support member Sta.

Protective layers 30 may be attached on surfaces of the transfer members 20. The protective layers 30 may include, for example, glass or plastic. The protective layers 30 may include ultrathin glass.

The protective layers 30, stamp layers 220, and base layers 210 may be sequentially stacked each other on the support members Sta.

For example, the transport member 40 may move to the support member Sta and may adsorb the top surface of an arbitrary transfer member 20 among the transfer members 20, which are aligned and disposed on the support member Sta. In another example, the support member Sta may move to the transport member 40 and may adsorb the top surface of an arbitrary transfer member 20 among the transfer members 20, which are aligned and disposed on the support member Sta. To this end, the transport member 40 may include one of an electrostatic chuck, an adhesive chuck, a vacuum chuck, and a porous vacuum chuck.

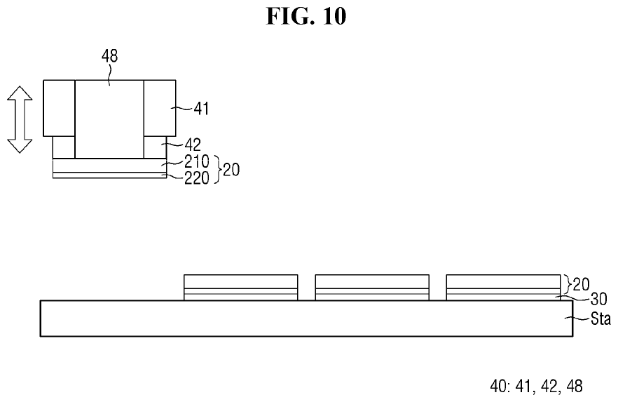

Thereafter, referring to FIG. 10, the protective layers 30 may be peeled off of the stamp layers 220.

The protective layers 30 may be removed with one of the transfer members 20 picked up and held by the transport member 40.

Thereafter, referring to FIG. 8, the transport member 40 picks up light-emitting elements LE from the donor substrate DS with the picked-up transfer member 20 (S120).

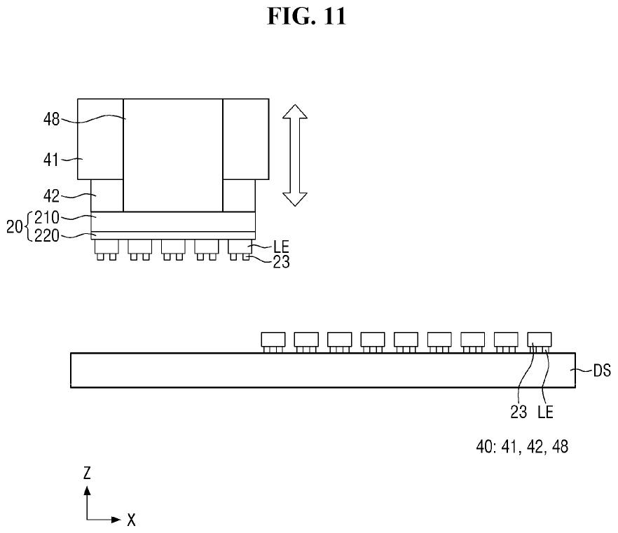

Referring to FIG. 11, the donor substrate DS where light-emitting elements LE are aligned and disposed is prepared. An adhesive material may be applied on the donor substrate DS. The donor substrate DS and the light-emitting elements LE may be bonded together by the adhesive material.

The transport member 40 moves the picked-up transfer member 20 to the donor substrate DS and bonds light-emitting elements LE onto the picked-up transfer member 20. Thereafter, the light-emitting elements LE are detached from the donor substrate DS by moving the transport member 40 in a third direction (or a Z-axis direction).

In order for the transport member 40 to be able to detach light-emitting elements LE from the donor substrate DS with the use of the picked-up transfer member 20, the adhesive force between the stamp layer 220 of the picked-up transfer member 20 and the light-emitting elements LE may be greater than the adhesive force between the donor substrate DS and the light-emitting elements LE. Also, the transport member 40 may apply a tensile force greater than the adhesive force between the donor substrate DS and the light-emitting elements LE, in the third direction (or the Z-axis direction).

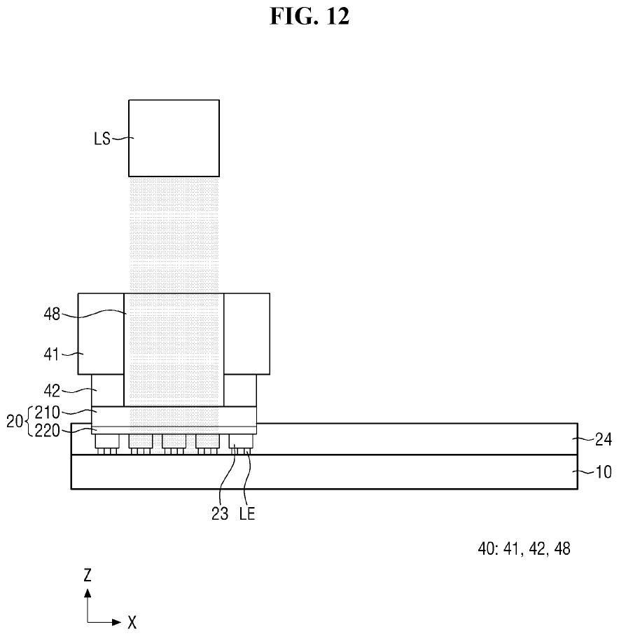

Light-emitting elements LE may include base substrates SSUB, n-type semiconductors NSEM, active layers MQW, p-type semiconductors PSEM, first contact electrodes CTE1, and second contact electrodes CTE2, as illustrated in FIG. 4, and may also include bonding electrodes 23. The bonding electrodes 23 may be the products of a pressure melting process using laser. The bonding of the bonding electrodes 23 will be described later with reference to FIG. 12.

Thereafter, referring to FIG. 8, light-emitting elements LE picked up by the transport member 40 are transferred onto the circuit substrate 10 and are bonded onto the circuit substrate 10 (S130).

Referring to FIG. 12, the circuit substrate 10 may correspond to the substrate SUB of FIG. 4, which may include the TFT layer “TFTL.”

A flux 24 may be applied on the circuit substrate 10 to have a selectable thickness. The flux 24 may be a material for facilitating the bonding of the circuit substrate 10 and the bonding electrodes 23 during a pressure melting process using laser. The flux 24 may include a natural or synthetic rosin, which is either oil-soluble or water-soluble. The flux 24 may be in liquid form or in gel form. After the pressure melting process, the flux 24 is removed.

The flux 24 may be applied to have a thickness less than that of the light-emitting elements LE, but the thickness of the flux 24 may be the same as, or even greater than, the height of the light-emitting elements LE, in some regions, due to the arrangement of the light-emitting elements LE. Thus, during a bonding process (for example, the pressure melting process), members that are in direct contact with the light-emitting elements LE may be contaminated by the flux 24. For example, in case that the head chuck 42 is in direct contact with the flux 24, the adsorption function of the head chuck 42 may deteriorate, and thus, a process of rinsing off the flux 24 may be required. However, as the picked-up transfer member 20 has a same size as, or a larger size than, the head chuck 42, the head chuck 42 may not be contaminated by the flux 24.

Thereafter, the light-emitting elements LE, which are targets to be bonded, may be disposed on the circuit substrate 10, and the bonding electrodes 23 may be disposed on the light-emitting elements LE. The picked-up transfer member 20 is disposed on the bonding electrodes 23 and overlaps the light-emitting elements LE. The laser transmitter 48 overlaps the picked-up transfer member 20. Accordingly, the bonding electrodes 23, the light-emitting elements LE, the picked-up transfer member 20, and the laser transmitter 48 overlap one another in the bonding area BZ.

The picked-up transfer member 20 may overlap not only the bonding area BZ, but also the non-bonding area NBZ. The picked-up transfer member 20 may include a transfer part 20-1, which overlaps the bonding area BZ, and an edge part 20-2, which overlaps the non-bonding area NBZ. As already mentioned above, in a plan view, as the non-bonding area NBZ surrounds the bonding area BZ, the edge part 20-2 may be formed to surround the transfer part 20-1.

In a case where the light-emitting elements LE are picked up from the donor substrate DS with the use of the picked-up transfer member 20, as described above with reference to FIG. 11, the light-emitting elements LE are bonded not only to the transfer part 20-1, but also to the edge part 20-2 of the picked-up transfer member 20.

As the edge part 20-2 does not overlap the bonding area BZ, as described above with reference to FIG. 12, the light-emitting elements LE bonded to the edge part 20-2 are not bonded to the circuit substrate 10.

As the heating member LS applies laser light to the bonding electrodes 23 with the picked-up transfer member 20 pressed with the transport head 41 and the laser transmitter 48, the laser light may be applied to the bonding electrodes 23 through the laser transmitter 48 and the picked-up transfer member 20. Accordingly, the heating member LS may apply heat to the bonding electrodes 23 up to the melting point of the bonding electrodes 23 so that the circuit substrate 10 and the bonding electrodes 23 may be pressure-melted and bonded. Here, the pressure melting process is a process in which the bonding electrodes 23 are melted by heat so that the light-emitting elements LE, anode pad electrodes APD, and cathode pad electrodes CPD are melted and fused together and cool and solidify in case that the supply of laser light is terminated. As the conductivity of the light-emitting elements LE, the anode pad electrodes APD, and the cathode pad electrodes CPD is maintained while the light-emitting elements LE, the anode pad electrodes APD, and the cathode pad electrodes CPD are cooling and solidifying from a molten state, the light-emitting elements LE, the anode pad electrodes APD, and the cathode pad electrodes CPD can be electrically and physically connected together.

The operations of the transport head 41 and the laser transmitter 48 may be controlled by the controller 300 of FIG. 1. For example, the controller 300 may control the transport head 41 based on data input from a pressure sensor (not illustrated) and a height sensor (not illustrated). The controller 300 may receive data from the pressure sensor and control the transport head 41 to reach a target pressure. Also, the controller 300 may receive data from the height sensor and control the transport head 41 and the laser transmitter 48 to reach a target height.

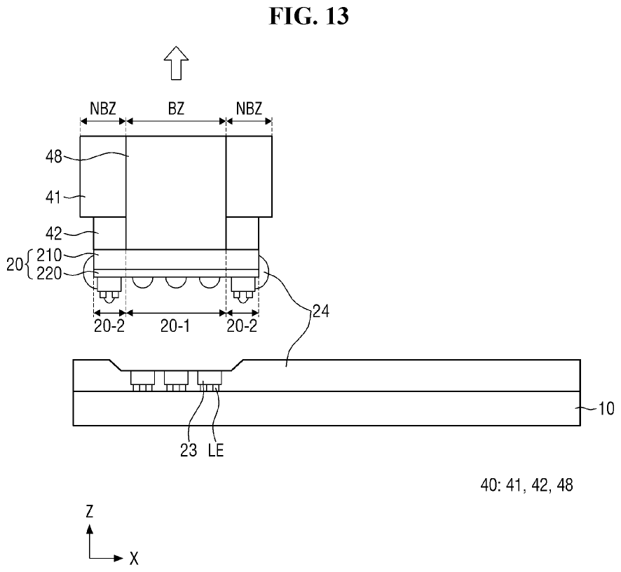

Referring to FIGS. 8 and 13, the transport member 40 separates the picked-up transfer member 20 from the circuit substrate 10 (S140).

For example, the transport member 40 is pulled in the third direction (or the Z-axis direction) with an attractive force greater than the adhesive force between the light-emitting elements LE, bonded onto the circuit substrate 10, and the picked-up transfer member 20.

The adhesive force between the light-emitting elements LE and the circuit substrate 10 may be greater than the adhesive force between the picked-up transfer member 20 and the head chuck 42, and the adhesive force between the picked-up transfer member 20 and the head chuck 42 may be greater than the adhesive force between the picked-up transfer member 20 and the light-emitting elements LE. Accordingly, in the case of applying a force in the third direction (or the Z-axis direction), the picked-up transfer member 20 may be detached from the light-emitting elements LE because of a relatively low adhesive force therebetween. Light-emitting elements LE having their edge parts 20-2 not bonded to the circuit substrate 10 may be detached even from the circuit substrate 10 together with the picked-up transfer member 20.

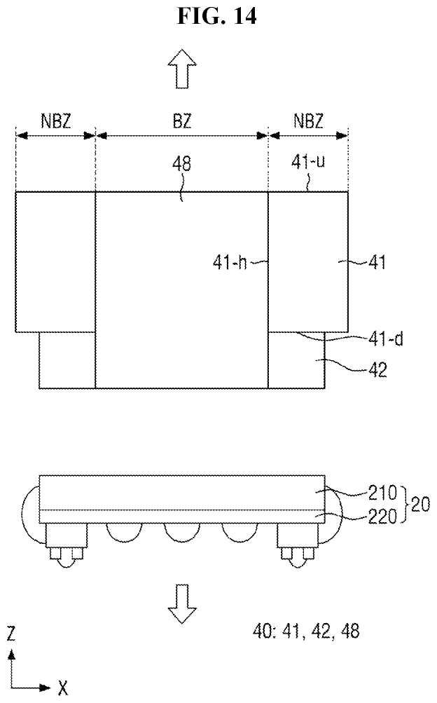

Referring to FIGS. 8 and 14, after the transfer and the bonding of the light-emitting elements LE to a first location L1, the transport member 40 detaches and removes the picked-up transfer member 20 (S150) by releasing the chuck function of the head chuck 42.

Thereafter, a determination is made as to whether the transfer and bonding of all batches of light-emitting elements LE to the circuit substrate 10 is complete (S160), and if the transfer and bonding of light-emitting elements LE to the circuit substrate 10 is not complete, the method returns to S110. Thereafter, as described above with reference to FIG. 8, the transport member 40 picks up another one of the transfer members 20 from the support member Sta.

Thereafter, the method proceeds to S120, and the transport member 40 picks up light-emitting elements LE from the donor substrate DS with the use of the picked-up transfer member 20.

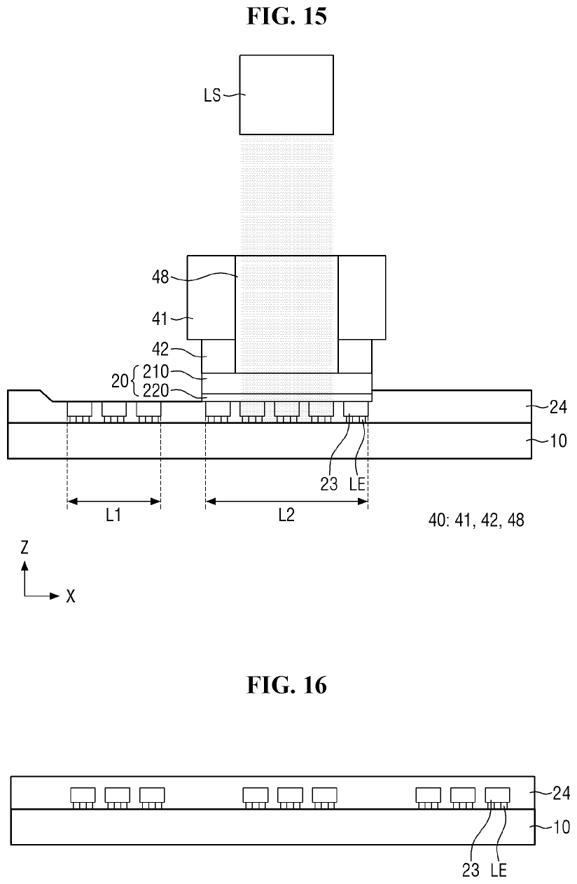

Thereafter, referring to FIG. 15, the method proceeds to S130, and the transport member 40 transfers and bonds the light-emitting elements LE onto the circuit substrate 10 with the use of the picked-up transfer member 20.

Here, the transport member 40 moves to a second location L2 and transfers and bonds the light-emitting elements LE to the second location L2.

Thereafter, the method proceeds to S140, and the transport member 40 separates the picked-up transfer member 20 from the circuit substrate 10. Thereafter, the method proceeds to S150, and the picked-up transfer member 20 is detached and removed from the transport member 40.

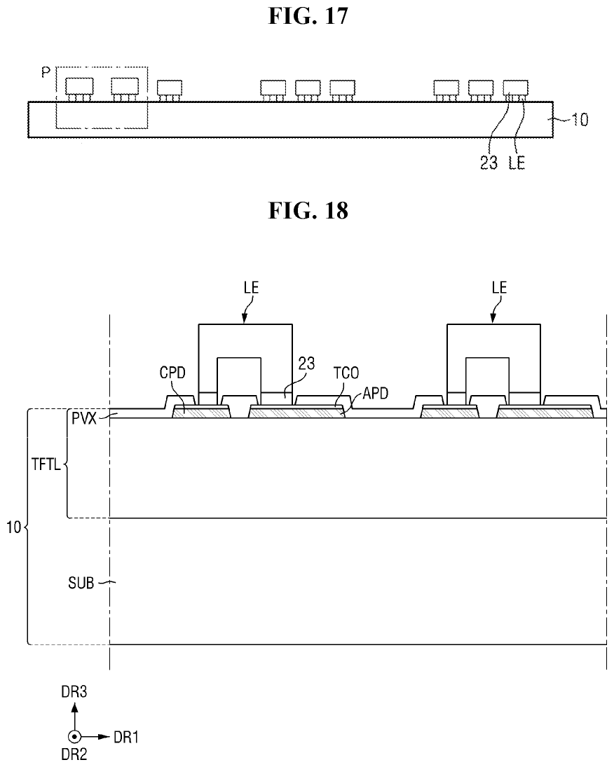

Thereafter, the method proceeds to S160, and a determination is made as to whether the transfer and bonding of all batches of light-emitting elements LE to the circuit substrate 10 is complete. Referring to FIGS. 8 and 17, if the transfer and bonding of all of the batches of light-emitting elements LE onto the circuit substrate 10 is complete, the flux 24 is removed from the circuit substrate 10 with light-emitting elements LE bonded thereon, with a flux cleaning agent (S170). Various flux cleaning agents (by way of example, a water-based flux cleaning agent) may be used to remove the flux 24. For example, CLEANTHROUGH 750HS or CLEANTHROUGH 750K manufactured by Kao Corporation or PINE ALPHA ST-100S manufactured by Arakawa Chemical Industries, Ltd., may be used to remove the flux 24, but the disclosure is not limited thereto.

Conditions for rinsing the circuit substrate 10 are not particularly limited. For example, the circuit substrate 10 may be rinsed at a temperature of about 30° C. to about 50° C. for about 1 to 5 minutes (by way of example, at a temperature of about 40° C. for about 2 to 4 minutes).

FIG. 18 is an enlarged schematic cross-sectional view of part P of FIG. 17.

Referring to FIG. 18, the light-emitting elements LE may be in contact with the anode pad electrodes APD and cathode pad electrodes CPD of the circuit substrate 10 through the bonding electrodes 23. As described above with reference to FIG. 4, first contact electrodes CTE1 of the light-emitting elements LE may be in contact with the anode pad electrodes APD of the circuit substrate 10, and second contact electrodes CTE2 of the light-emitting elements LE may be in contact with the cathode pad electrodes CPD.

The light-emitting elements LE are illustrated as being flip chip light-emitting elements, but the disclosure is not limited thereto. By way of example, vertical light-emitting elements may be used as the light-emitting elements LE.

As already mentioned above, as the bonding of the light-emitting elements LE can be performed with the use of the transport member 40 with a transfer member 20 attached to the transport member 20, the convenience of processing can be improved.

Also, as disposable transfer members 20 that are detachable from the transport head 41 are used, the adhesion of any pollutant (for example, the flux 24) onto the transfer members 20 does not need to be considered.

Also, as transfer members 20 that are larger than the head chuck 42 of the transport head 41 are used, the contamination of the head chuck 42 does not need to be considered.

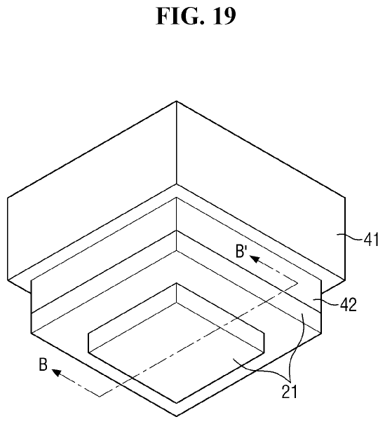

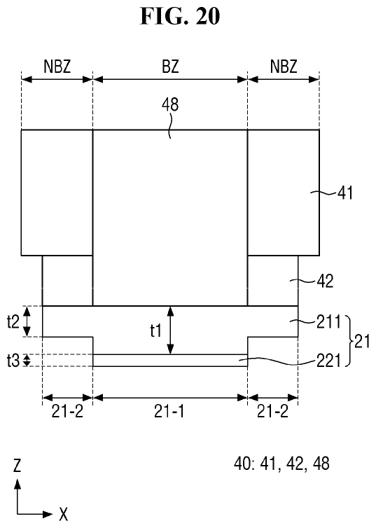

FIG. 19 is a schematic perspective view of a transfer member and a transport member according to an embodiment, and FIG. 20 is a schematic cross-sectional view taken along line B-B′ of FIG. 19.

Referring to FIGS. 19 and 20, a transport member 40 may include a transport head 41, a head chuck 42, and a laser transmitter 48. The transport member 40 is similar to its counterpart of FIGS. 6 and 7, and thus, a detailed description thereof will be omitted.

A transfer member 21 may include a base layer 211 and a stamp layer 221, which is disposed on the base layer 211. The transfer member 21 may be formed of a same material or a similar material as the transfer member 20 of FIG. 5. For example, the transfer member 21 may be formed of a material capable of transmitting laser light therethrough, and the base layer 211 may include, for example, glass or plastic. The stamp layer 221 may be formed of an adhesive material or a sticky material. The adhesive material may be, for example, an OCA or a PSA, and the sticky material may be, for example, an acrylic material, a urethane-based material, or a silicone-based material. The stamp layer 221 may be formed to be thinner than the base layer 211. The base layer 211 and the stamp layer 221 may be formed to have a same area.

One surface or a surface of the base layer 211 may be adsorbed to the head chuck 42.

The base layer 211 may be formed to be stepped between a bonding area BZ and a non-bonding area NBZ. The base layer 211 may be formed to have a first thickness t1 in the bonding area BZ and a second thickness t2 in the non-bonding area NBZ. Here, the first thickness t1 may be greater than the second thickness t2. For example, the base layer 211 may be formed to be relatively thick in the bonding area BZ and relatively thin in the non-bonding area NBZ. The stamp layer 221 may be formed to have the second thickness t2 or a thickness t3 less than the second thickness t2.

The stamp layer 221 may overlap the bonding area BZ, but not with the non-bonding area NBZ.

The transfer member 21 may include a transfer part 21-1, which overlaps the bonding area BZ, and an edge part 21-2, which overlaps the non-bonding area NBZ. The transfer part 21-1 may include both the base layer 211 and the stamp layer 221, but the edge part 21-2 may include only the base layer 211.

The transfer part 21-1 may overlap the bonding area BZ, but not with the non-bonding area NBZ. The edge part 21-2 may overlap the non-bonding area NBZ, but not with the bonding area BZ.

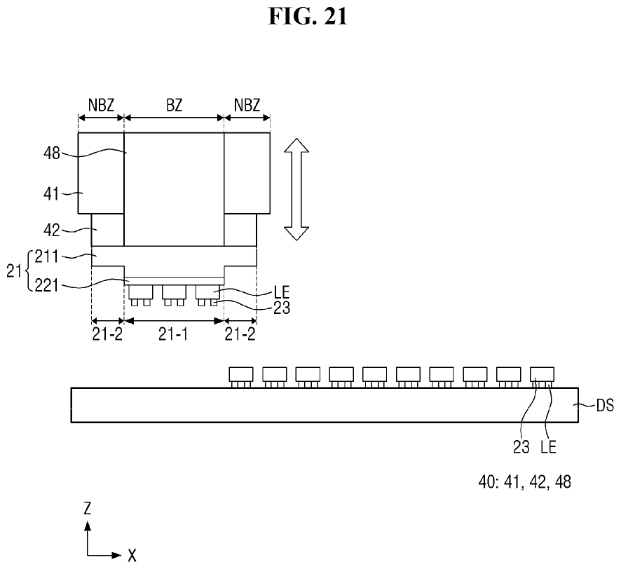

FIGS. 21 through 26 are schematic cross-sectional views illustrating a method of fabricating a display panel using the transfer member and the transport member of FIGS. 19 and 20.

Referring to FIG. 8, the transport member 40 moves to a support member Sta and picks up one of transfer members 21, which are disposed on the support member Sta (S110).

Here, as already mentioned above with reference to FIG. 9, the support member Sta supports the transfer members 21. Referring to FIGS. 20 and 21, each of the transfer members 21 may include a base layer 211, which is stepped, and a stamp layer 221, which is disposed on the base layer 211.

The transport member 40 may adsorb the top surface of an arbitrary transfer member 21 (or the surface of the base layer 211 of the arbitrary transfer member 21) among the transfer members 21 aligned on the support member Sta, to the head chuck 42 with a chuck function.

Thereafter, referring to FIGS. 8 and 21, the transport member 40 picks up light-emitting elements LE from a donor substrate DS with the use of the picked-up transfer member 21 (S120).

S120 is as described above with reference to FIG. 11, and thus, a detailed description thereof will be omitted. However, in an embodiment of FIG. 21, unlike in an embodiment of FIG. 11, the picked-up light-emitting elements LE can be prevented from being adhered onto an edge part 21-1 of the picked-up transfer member 21 because the stamp layer 221 is formed only in a transfer part 21-1 of the picked-up transfer member 21.

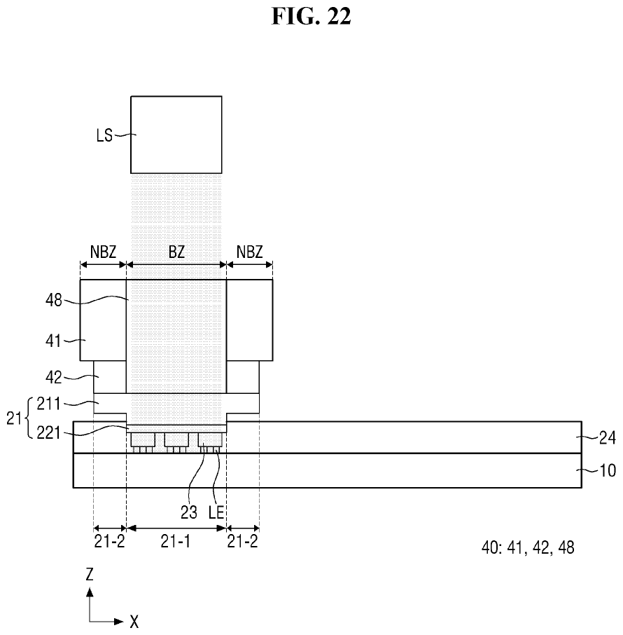

Thereafter, referring to FIGS. 8 and 22, the transport member 40 transfers the picked-up light-emitting elements LE onto a circuit substrate 10 with a flux 24 applied thereon, and bonds the picked-up light-emitting elements LE onto the circuit substrate 10 (S130) by applying laser light to bonding electrodes 23 through the transport member 40 with the use of a heating member LS.

The bonding electrodes 23, the picked-up light-emitting elements LE, the picked-up transfer member 21, and the laser transmitter 48 overlap one another in the bonding area BZ. The bonding of the picked-up light-emitting elements LE through the application of laser light is as described above with reference to FIG. 12, and thus, a detailed description thereof will be omitted.

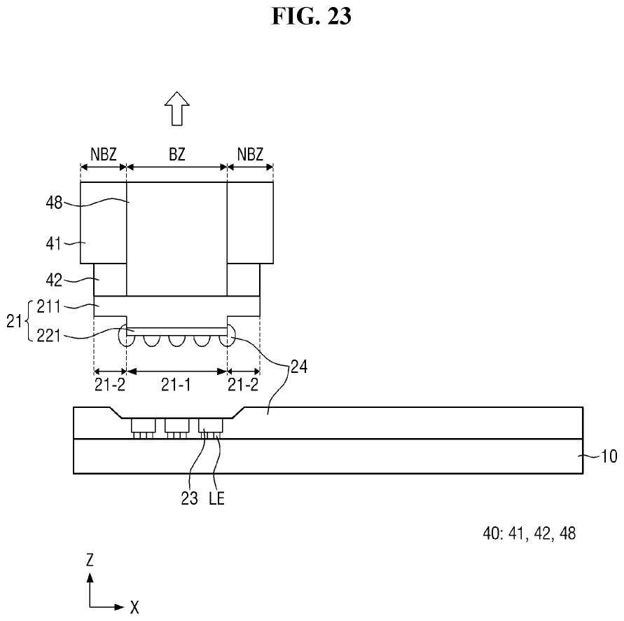

Referring to FIGS. 8 and 23, the transport member 40 may separate the picked-up transfer member 21 from the circuit substrate 10 (S140).

For example, the transport member 40 is pulled in a third direction (or a Z-axis direction) with an attractive force greater than the adhesive force between the picked-up light-emitting elements LE, bonded onto the circuit substrate 10, and the picked-up transfer member 21. S140 is as described above with reference to FIG. 13, and thus, a detailed description thereof will be omitted. However, in an embodiment of FIG. 23, unlike in an embodiment of FIG. 13, the picked-up light-emitting elements LE can be bonded onto the circuit substrate 10, almost without being lost, because the stamp layer 221 is formed only in the transfer part 21-1 of the picked-up transfer member 21.

Thereafter, referring to FIG. 8, after the transfer and bonding of a current batch of light-emitting elements LE, the transport member 40 detaches and removes the picked-up transfer member 21 (S150) by releasing the chuck function of the head chuck 42.

Thereafter, referring to FIG. 8, a determination is made as to whether the transfer and bonding of all batches of light-emitting elements LE to the circuit substrate 10 is complete (S160), and if the transfer and bonding of all batches of light-emitting elements LE to the circuit substrate 10 is not complete, the method returns to S110 so that S110, S120, S130, S140, S150, and S160 may be performed again.

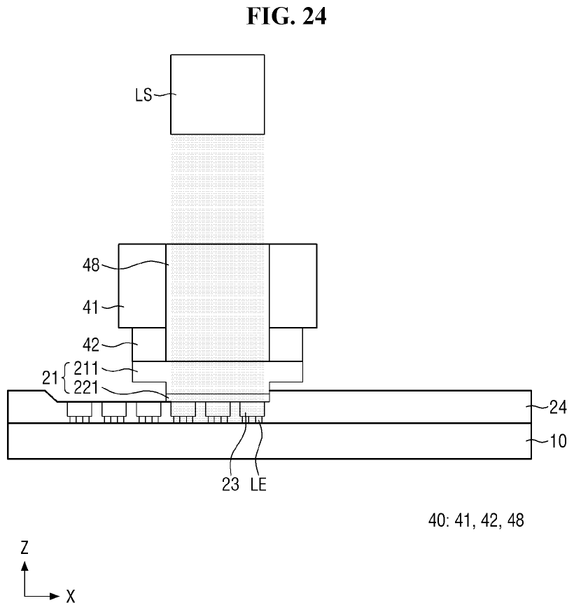

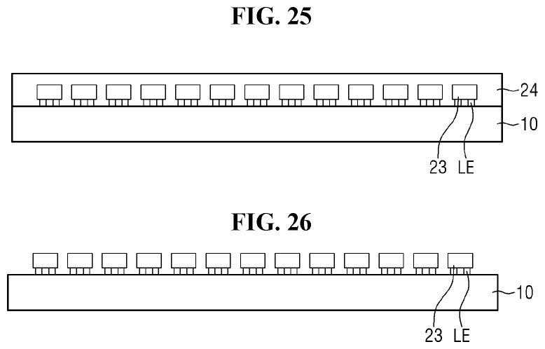

Referring to FIGS. 24 and 25, the distance between batches of light-emitting elements LE can be uniformly controlled by using transfer members 21 having a step difference.

On the contrary, referring to FIG. 15, batches of light-emitting elements LE transferred and bonded onto the circuit substrate 10 may be spaced apart by as much as the length of edge parts 20-1 of transfer members 20 because light-emitting elements LE transferred by the edge parts 20-1 are not bonded onto the circuit substrate 10, but removed together with the transfer members 20.

Thereafter, referring to FIG. 26, if a determination is made in S160 that the transfer and bonding of all batches of light-emitting elements LE onto the circuit substrate 10 is complete, the flux 24 may be removed from the circuit substrate 10 with light-emitting elements LE bonded thereon, with a flux cleaning agent with a flux cleaning agent (S170).

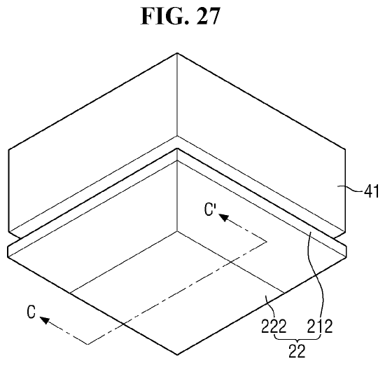

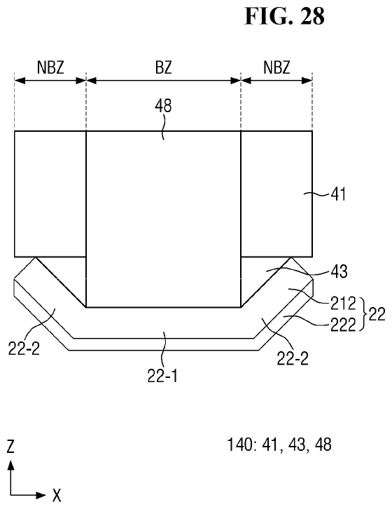

FIG. 27 is a schematic perspective view of a transfer member and a transport member according to an embodiment, and FIG. 28 is a schematic cross-sectional view taken along line C-C′ of FIG. 27.

Referring to FIGS. 27 and 28, a transport member 140 may include a transport head 41, a head chuck 43, and a laser transmitter 48. The transport head 41 and the laser transmitter 48 are similar to their respective counterparts of FIGS. 6 and 7, and detailed descriptions thereof will be omitted.

A transfer member 22, like its counterpart of FIG. 5, may be formed of a material capable of transmitting laser light therethrough and may include a base layer 212 and a stamp layer 222, which is disposed on the base layer 212.

The transfer member 22 may be formed of a same material or a similar material as the transfer member 20 of FIG. 5. For example, the transfer member 22 may be formed of a material capable of transmitting laser light therethrough, and the base layer 212 may include, for example, glass or plastic. The stamp layer 222 may be formed of an adhesive material or a sticky material. The adhesive material may be, for example, an OCA or a PSA, and the sticky material may be, for example, an acrylic material, a urethane-based material, or a silicone-based material. The stamp layer 222 may be formed to be thinner than the base layer 212. The base layer 212 and the stamp layer 222 may be formed to have a same area.

The transfer member 22 may include a transfer part 22-1, which overlaps a bonding area BZ, and an edge part 22-2, which overlaps a non-bonding area NBZ.

The transfer part 22-1 may overlap the bonding area BZ, but not with the non-bonding area NBZ. The edge part 22-2 may overlap the non-bonding area NBZ, but not with the bonding area BZ.

The edge part 22-2 may be folded from the transfer part 22-1 along the boundaries with the transfer part 22-1. The edge part 22-2 may be folded along the slopes of the head chuck 43. By way of example, incision grooves may be formed along the boundaries between the transfer part 22-1 and the edge part 22-2, in which case, the folding of the edge part 22-2 can be facilitated.

The head chuck 43 may be disposed in the non-bonding area NBZ of the transport member 140 and may not overlap the bonding area BZ.

The transport head 41, the head chuck 43, and the edge part 22-2 are disposed to overlap the non-bonding area NBZ, and the laser transmitter 48 and the transfer part 22-2 are disposed to overlap the bonding area BZ.

The head chuck 43 may be formed to surround the side surfaces of the laser transmitter 48. The head chuck 43 may form an acute angle with the transport head 41.

The head chuck 43 may be attachable to, or detachable from, the transfer member 22 via a chuck function. For example, the head chuck 43 may include any one of an electrostatic chuck, an adhesive chuck, a vacuum chuck, and a porous vacuum chuck.

The head chuck 43 may adsorb the top surface of the transfer member 22.

The head chuck 43 may adsorb the surface of the base layer 212 of the edge part 22-2 of the transfer member 22.

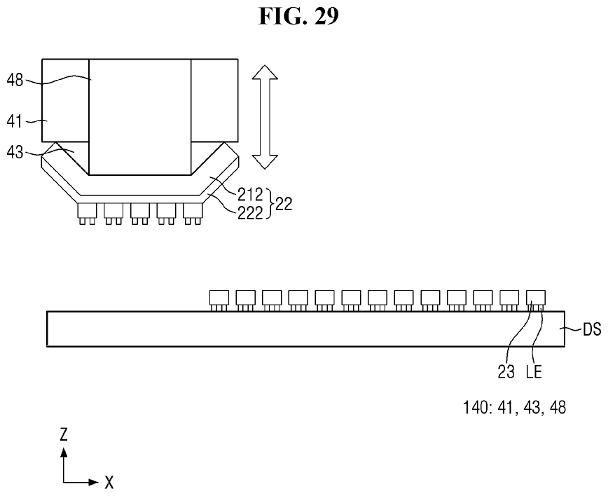

FIGS. 29 through 34 are schematic cross-sectional views illustrating a method of fabricating a display panel using the transfer member and the transport member of FIGS. 27 and 28.

Referring to FIG. 8, the transport member 140 moves to a support member Sta and picks up one of transfer members 22, which are disposed on the support member Sta (S110).

Here, as already mentioned above with reference to FIG. 9, the support member Sta supports the transfer members 22. Referring to FIGS. 27 and 28, each of the transfer members 22 may include a transfer part 22-1 and an edge part 22-2.

The transport member 140 may adsorb the top surface of an arbitrary transfer member 22 (or the surface of the base layer 212 of the arbitrary transfer member 22) among the transfer members 22 aligned on the support member Sta, to the head chuck 42 with a chuck function.

Thereafter, referring to FIGS. 8 and 29, the transport member 140 picks up light-emitting elements LE from a donor substrate DS with the use of the picked-up transfer member 22 (S120).

S120 is as described above with reference to FIG. 11, and thus, a detailed description thereof will be omitted. However, in an embodiment of FIG. 29, unlike in an embodiment of FIG. 11, as the edge part 22-2 of the picked-up transfer member 22 is folded toward the head chuck 43, the number of light-emitting elements LE adhered to the edge part 22-2 can be reduced.

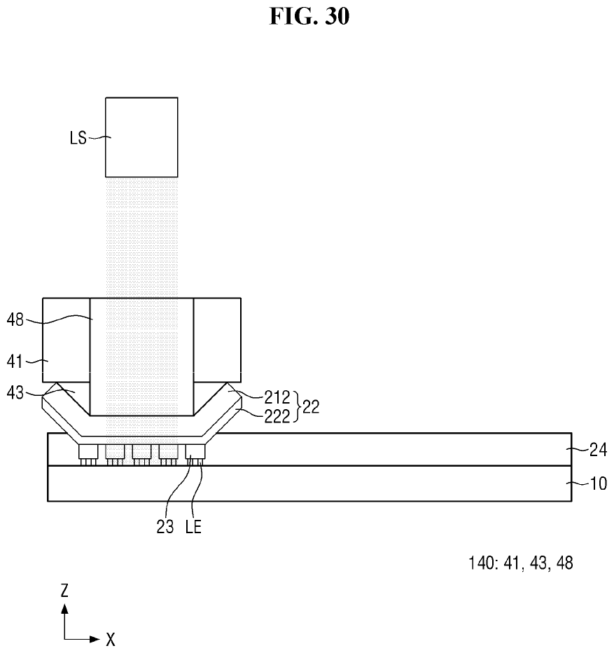

Thereafter, referring to FIGS. 8 and 30, the transport member 140 transfers the picked-up light-emitting elements LE onto a circuit substrate 10 with a flux 24 applied thereon, and bonds the picked-up light-emitting elements LE onto the circuit substrate 10 (S130) by applying laser light to bonding electrodes 23 through the transport member 140 with the use of a heating member LS.

The bonding electrodes 23, the picked-up light-emitting elements LE, the picked-up transfer member 22, and the laser transmitter 48 overlap one another in the bonding area BZ. The bonding of the picked-up light-emitting elements LE through the application of laser light is as described above with reference to FIG. 12, and thus, a detailed description thereof will be omitted.

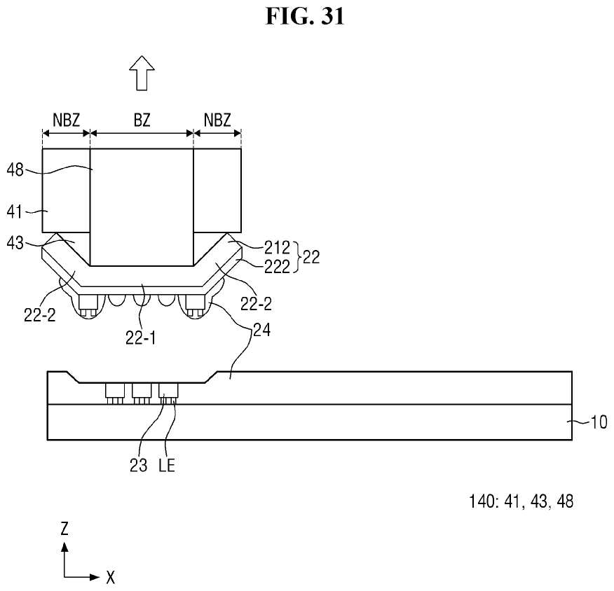

Referring to FIGS. 8 and 31, the transport member 140 may separate the picked-up transfer member 22 from the circuit substrate 10 (S140).

For example, the transport member 140 is pulled in a third direction (or a Z-axis direction) with an attractive force greater than the adhesive force between the picked-up light-emitting elements LE, bonded onto the circuit substrate 10, and the picked-up transfer member 22. S140 is as described above with reference to FIG. 13, and thus, a detailed description thereof will be omitted. However, in an embodiment of FIG. 31, unlike in an embodiment of FIG. 13, the picked-up light-emitting elements LE can be bonded onto the circuit substrate 10, almost without being lost, because the edge part 22-2 of the picked-up transfer member 22 is folded along the head chuck 43.

Thereafter, referring to FIG. 8, after the transfer and bonding of a current batch of light-emitting elements LE, the transport member 140 detaches and removes the picked-up transfer member 22 by releasing the chuck function of the head chuck 42 (S150).

Thereafter, referring again to FIG. 8, a determination is made as to whether the transfer and bonding of all batches of light-emitting elements LE to the circuit substrate 10 is complete (S160), and if the transfer and bonding of all batches of light-emitting elements LE to the circuit substrate 10 is not complete, the method returns to S110 so that S110, S120, S130, S140, S150, and S160 may be performed again.

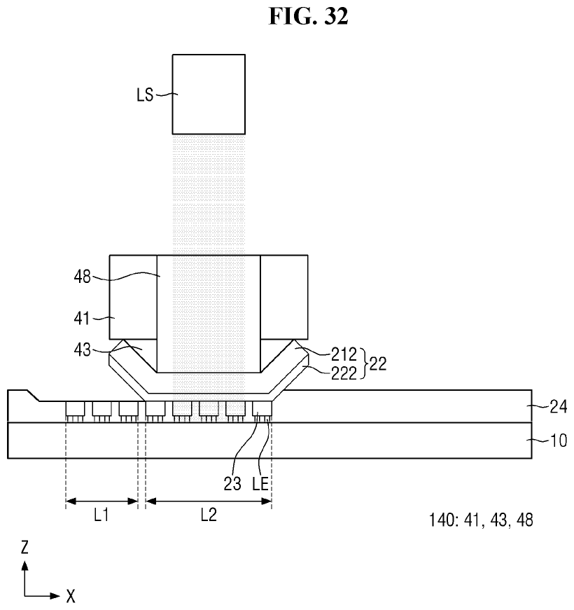

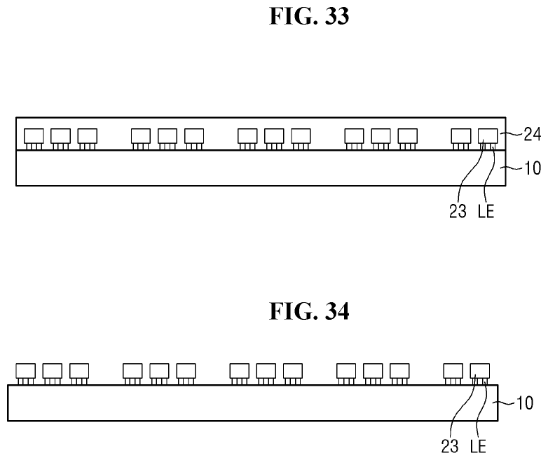

Referring to FIGS. 32 and 33, batches of light-emitting elements LE transferred and bonded onto the circuit substrate 10 may be spaced apart by a distance greater than the width of the light-emitting elements LE because light-emitting elements LE transferred by the boundaries between transfer parts 22-1 and edge parts 22-2 of transfer members 22 are not bonded onto the circuit substrate 10, but removed together with the transfer members 22.

Thereafter, referring to FIG. 34, if a determination is made in S160 that the transfer and bonding of all batches of light-emitting elements LE onto the circuit substrate 10 is complete, the flux 24 may be removed from the circuit substrate 10 with light-emitting elements LE bonded thereon, with a flux cleaning agent with a flux cleaning agent (S170).

After the transfer of light-emitting elements, the bonding of the light-emitting elements can be performed with the use of a transport member with a laser transmitter by applying laser light without the need to move the transport member or without a requirement of other members. Accordingly, the fabrication of a display panel can be simplified.

Also, any transfer defects that may be caused by contaminated transfer members can be addressed by transferring light-emitting elements from a donor substrate onto a circuit substrate with the use of disposable transfer members.

However, the aspects of the disclosure are not restricted to those set forth herein. The above and other aspects of the disclosure will become more apparent to one of daily skill in the art to which the disclosure pertains by referencing the claims, and equivalents thereof to be included therein.

What is claimed is:

1. An apparatus for fabricating a display panel, comprising:
a transfer member having adhesiveness or stickiness that bonds to light-emitting elements; and
a transport member transferring and bonding light-emitting elements which are aligned on a donor substrate of the light-emitting elements onto a circuit substrate by the transfer member,
wherein the transport member includes:
a laser transmitter formed of a material that transmits laser light;
a transport head that moves vertically and horizontally and surrounds side surfaces of the laser transmitter; and
a head chuck disposed on a surface of the transport head to surround the side surfaces of the laser transmitter, having an adsorption function, and attached to, or detached from, the transfer member.

2. The apparatus of claim 1, wherein the transfer member includes:
a stamp layer that has adhesiveness or stickiness; and
a base layer that is disposed on a surface of the stamp layer, and is formed of a material that transmits laser light.

3. The apparatus of claim 2, wherein the head chuck is attachable to, or detachable from the base layer.

4. The apparatus of claim 2, wherein the transfer member includes:
a transfer part that overlaps the laser transmitter in a plan view and
an edge part that overlaps the head chuck in a plan view.

5. The apparatus of claim 4, wherein an edge part of the base layer is thinner than a transfer part of the base layer.

6. The apparatus of claim 5, wherein the stamp layer is formed only in the transfer part.

7. The apparatus of claim 4, wherein the head chuck forms a substantially acute angle with the transport head.

8. The apparatus of claim 7, wherein the edge part is folded along slopes of the head chuck.

9. The apparatus of claim 1, wherein the light-emitting elements include:
n-type semiconductors;
active layers;
p-type semiconductors;
first contact electrodes and second contact electrodes; and
bonding members on surfaces of the first contact electrodes and surfaces of the second contact electrodes.

10. The apparatus of claim 9, further comprising:
a heating member applying laser light to the bonding members through the laser transmitter and the transfer member.

11. The apparatus of claim 1, wherein the circuit substrate includes a flux applied on a surface of the circuit substrate.

12. A method of fabricating a display panel, comprising:
adsorbing, by a transport member, a transfer member by a chuck;
picking up, by the transport member, light-emitting elements from a donor substrate by the transfer member;
bonding, by the transport member, the light-emitting elements onto a circuit substrate by the transfer member by placing the light-emitting elements on the circuit substrate and applying laser light;
separating, by the transport member, the transfer member from the circuit substrate; and
detaching, by the transport member, the transfer member by releasing the chuck.

13. The method of claim 12, further comprising:
rinsing off a flux from the circuit substrate in case that the bonding of the light-emitting elements onto the circuit substrate is complete.

14. The method of claim 12, wherein the transfer member includes:
a stamp layer that has adhesiveness or stickiness; and
a base layer that is disposed on a surface of the stamp layer, and is formed of a material that transmits laser light.

15. The method of claim 14, wherein the transport member includes:
a laser transmitter formed of a material that transmits laser light;
a transport head that moves vertically and horizontally and surrounds side surfaces of the laser transmitter; and
a head chuck disposed on a surface of the transport head to surround the side surfaces of the laser transmitter, having an adsorption function, and attached to, or detached from, the transfer member.

16. The method of claim 15, wherein the light-emitting elements include:
n-type semiconductors;
active layers;
p-type semiconductors;
first contact electrodes and second contact electrodes; and
bonding members on surfaces of the first contact electrodes and surfaces of the second contact electrodes.

17. The method of claim 16, wherein the bonding of the light-emitting elements onto the circuit substrate, comprises placing, by the transport member, the light-emitting elements such that the laser transmitter, the transfer member, the light-emitting elements, the bonding members, and the circuit substrate overlap in a plan view.

18. The method of claim 17, wherein a heating member applies laser light to the bonding members through the laser transmitter and the transfer member

19. The method of claim 15, wherein
the transfer member includes a transfer part that overlaps the laser transmitter in a plan view and an edge part disposed that overlaps the head chuck in a plan view, and
the stamp layer is formed only in the transfer part.

20. The method of claim 15, wherein the head chuck forms a substantially acute angle with the transport head.

21. The method of claim 20, wherein
the transfer member includes a transfer part that overlaps the laser transmitter in a plan view and an edge part that overlaps the head chuck in a plan view, and
the adsorbing of the transfer member by the chuck, comprises folding the edge part along slopes of the head chuck.
